(19) United States
(12) Patent Application Publication
(10) Pub. No.: US 2012/0040477 A1
(43) Pub. Date: Feb. 16, 2012

(54) AI EPOXY ADJUSTMENT

(76) Inventors: Frank Yu, Chung Ho City (TW); Eric Hsieh, Chung Ho City (TW); Ares Twu, Chung Ho City (TW); W. L. Hsu, Chung Ho City (TW)

(21) Appl. No.: 12/856,180

(22) Filed: Aug. 13, 2010

(51) Int. Cl. H01L 21/66; B05C 5/00

(52) U.S. Cl. 438/15; 156/356; 257/E21.53

(57) ABSTRACT

A method and apparatus for dispensing a volume of die attach adhesive onto a surface can include an optical system which images the dispensed volume of die attach adhesive. A two-dimensional area covered by the die attach adhesive and a die attach dispense pressure can be used as a comparison with a reference value to determine whether the volume of die attach adhesive dispensed is sufficient. The reference value can take into account viscosity changes of the die attach adhesive, so that the volume of die attach adhesive dispensed during production can be determined. The volume dispensed can be automatically adjusted in situ during production using a computer system.

### FIELD OF THE INVENTION

The present teachings relate to the field of semiconductor device manufacture and, more particularly, to the attachment of a semiconductor die to a receiving substrate using a die attach adhesive.

### BACKGROUND OF THE INVENTION

During the formation of a semiconductor device such as a memory device, a logic device, etc., a semiconductor die can be attached to a receiving substrate such as a die pad of a lead frame, then encapsulated in a resin encapsulation. Typically, a quantity of die attach adhesive, for example a conductive epoxy, is dispensed onto the lead frame in a particular pattern which enhances adhesion, and the die is placed into the adhesive using a measured force. A “scrub” may be employed by moving the die in the X and Y directions relative to the lead frame to remove voids from the adhesive and to enhance contact between the die, the adhesive, and the lead frame.

The quantity of die attach adhesive dispensed onto the lead frame should be sufficient to ensure a strong attachment between the die and the receiving substrate. A deficiency of material can result in the die detaching from the lead frame during use, resulting in failure of the semiconductor device. Excess material can result in adhesive deposits on a circuit side of the die, which can interfere with attachment of bond wires or damage the circuitry of the die.

To insure that the dispensed quantity of die attach adhesive is sufficient, a post bond inspection (FBI) process is typically employed after the die has been attached to the lead frame to determine whether the quantity of die attach adhesive is sufficient. In one PBI method, an optical system produces a plan view image of the die and lead frame which is used to measure a die attach fillet to determine if a quantity of dispensed die attach adhesive is correct. If a width of the fillet is insufficient or the fillet is discontinuous, it is assumed that the quantity of die attach adhesive is insufficient. If the width of the fillet is too great or die attach adhesive is located on a circuit side of the die, an overabundance of adhesive is assumed.

The measured amount of die attach adhesive between the die and the lead frame should be within a desired range. If the quantity of die attach adhesive varies from the target value by more than a predetermined value as determined at PBI, the device is reworked or scrapped. A die bond operator can regulate the dispensed quantity of die attach adhesive by manually adjusting a dispensing pressure used to dispense the die attach adhesive from a syringe which contains the die attach adhesive.

### SUMMARY OF THE EMBODIMENTS

In contemplating current methods of controlling the quantity of die attach adhesive dispensed onto the lead frame, the inventors have realized various deficiencies.

For example, the inventors have realized that measurement of a quantity of die attach adhesive prior to die attach would be useful. Further, the inventors have realized that a viscosity of the die attach adhesive can vary between lots. Additionally, die attach adhesive viscosity can change with fluctuating die attach temperatures, and can also vary depending on the amount of adhesive remaining within the syringe.

As viscosity varies, an incorrect quantity of die attach adhesive can be dispensed. With a lower viscosity, more adhesive will be dispensed for a given dispense pressure and can result in a PBI measurement which indicates that excessive material has been dispensed. With a higher viscosity, less adhesive will be dispensed for the given dispense pressure which can result in a PBI measurement which indicates that an insufficient quantity of material has been dispensed. Somewhat related to viscosity, the density of the liquid material may also change slightly across lots and with changing temperatures.

Additionally, the dispensed volume of die attach adhesive is changed by manually adjusting the dispense pressure on a syringe by an operator. To correctly adjust the syringe output, the operator must be trained, and the task requires a certain amount of experience to complete correctly and in a minimum amount of time. The inventors have realized that an automated system for altering the volume of die attach adhesive dispensed onto a surface would be useful.

In considering these and other deficiencies in the die attach process, the inventors have realized that an automated process for more accurately measuring the quantity of die attach adhesive dispensed would be desirable. Further, they have realized that an automated process for altering the quantity of die attach adhesive dispensed based on the viscosity of the die attach adhesive would be useful. However, measuring the viscosity using a sampling technique would be time consuming and inefficient.

Thus the inventors have developed an automated, in situ process and system for measuring the quantity of dispensed die attach adhesive prior to the die being attached which also considers the viscosity of the adhesive. Further, the disclosed automated system can alter the volume of adhesive dispensed based on the viscosity of the adhesive.

For example, an embodiment of the present teachings can include dispensing a volume of adhesive onto a surface using a known pressure and duration, imaging the dispensed volume of adhesive with an imager such as a digital imager, and comparing data from the image with data with reference data to determine whether the dispensed volume of adhesive is sufficient. The reference data can be obtained through prior testing of dispensed adhesives of known composition and viscosity with known dispensing pressures and durations. The comparison can be performed through the use of a computer system. Imaging of the volume of adhesive can be performed prior to attaching a semiconductor die.

If it is determined that the dispensed volume of adhesive is not within a predefined (i.e. target) range, the volume can be reworked or the surface can be scrapped, and the volume of adhesive dispensed can be changed. In another embodiment, the target range is set so that even though a dispensed volume of adhesive may be outside the target range, the dispensed volume is still within a range which is acceptable for die attach. Thus a die can be attached using the adhesive volume which is measured to be outside the target range, and the volume of adhesive to be dispensed can be changed before the dispensed volume requires rework or scrap.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1 is a flow chart of an embodiment of the present teachings;

FIG. 2 is a depiction of a plan view image which can be produced by an imager in accordance with an embodiment of the present teachings;

FIG. 3 is a flow chart of an embodiment of the present teachings;

FIG. 4 is a cross section depicting dispensing of a die attach adhesive in accordance with an embodiment of the present teachings;

FIG. 5 is a schematic cross section depicting an embodiment of the present teachings; and

FIG. 6 is a cross section depicting the attachment of a semiconductor die to a surface with a die attach adhesive in accordance with an embodiment of the present teachings.

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Reference will now be made in detail to exemplary embodiments of the present teachings which are illustrated in the accompanying drawings. Wherever possible, the same reference numbers will be used throughout the drawings to refer to the same or like parts.

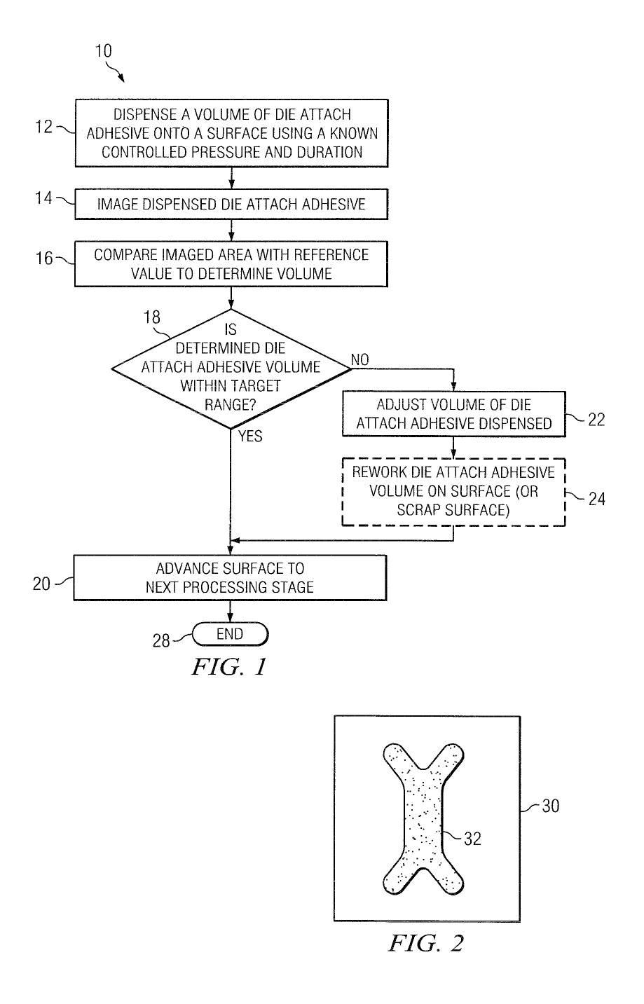

A first exemplary process for dispensing and inspecting a volume of die attach adhesive in accordance with an embodiment of the present teachings is shown in the flow chart of FIG. 1. The process 10 begins at 12 with a volume (quantity) of die attach adhesive being dispensed onto a surface such as a lead frame die pad. The adhesive can be located within, and dispensed from, a container such as a syringe. The adhesive can be dispensed using one or more techniques, such as by applying a controlled, measured (i.e. known) pressure to a plunger, or by increasing the atmospheric pressure within the container using air pressure, etc., for a known duration of time. The die attach adhesive can include conductive and/or dielectric fluid materials such as silver-filled epoxies, aluminum-filled epoxies, unfilled epoxies, polyimides, etc. Both the dispense pressure and duration of time are known and controlled.

Once the die attach adhesive is dispensed 12 onto the surface, the adhesive is imaged 14, for example using an optical system which produces a plan view pixel image of the dispensed adhesive on the lead frame die pad. FIG. 2 represents an image of a surface 30, such as a lead frame die pad, having a dispensed quantity of die attach adhesive 32 prior to attaching a semiconductor wafer section such as a semiconductor die. In various embodiments, an optical system similar to that used at post bond inspection can be used. In another embodiment, the same optical system can be used to image the dispensed adhesive as well as perform a post bond inspection. A two dimensional area covered by the dispensed adhesive 32 is measured.

Next, the imaged area of the die attach adhesive dispensed using the known dispense pressure and dispense duration is compared with a reference value (16 of FIG. 1) to determine a volume of the adhesive dispensed. One or more reference values can be previously determined during process testing. For example, if a two dimensional (2D) surface area is measured to be 28 mm², the volume of die attach adhesive dispensed at the known pressure and duration for 28 mm² might be 11 mm³. Table 1 is an exemplary lookup table for an aluminum-filled epoxy which can be produced by testing during process engineering. Each die attach adhesive can have a separate lookup table, for example to account for varying viscosities and other characteristics which differ between different materials.

TABLE 1
Exemplary Lookup Table Values

| 2D Surface Area (mm²) | Volume (mm³) |
|---|---|
| 14 | 5.85 |
| 21 | 8.43 |
| 28 | 11 |
| 35 | 13.54 |

Instead of a lookup table, the reference value can include optical images of known volumes of die attach adhesive. The optical images of the known volumes can be compared with the optical image of the dispensed volume of die attach adhesive to determine the volume of the dispensed adhesive.

If the determined volume is within a target range of the reference value 18, the surface with the dispensed die attach adhesive is advanced to the next processing stage 20, such as a die attach stage. If the determined volume of die attach adhesive is not within a target range of the target value, the quantity of die attach adhesive dispensed onto successive lead frames can be adjusted 22. To adjust the quantity of dispensed adhesive, an operator can manually adjust the dispense pressure on the syringe, or another method as described below can be used.

Because the volume of die attach adhesive is determined prior to attaching the die, the volume of die attach adhesive, if out of range, can be reworked 24, then the assembly is advanced to the next processing stage 20, such as a die attach process. In an alternate process, if the volume of die attach adhesive is out of range, the surface is scrapped prior to die attachment. Where possible, however, the target range of the die attach volume at 18 is set such that even if the volume is outside the target range, the dispensed volume can be adjusted at 22 but the device with the volume which is outside the target range will not need to be scrapped or reworked. Thus box 24 is shown as a dotted line, as rework or scrap is avoided where possible by adjusting the adhesive volume at 22 before scrap or rework is necessary.

A viscosity of a die attach adhesive may not be constant across an entire container such as a syringe which is used to dispense the adhesive. This can result from the compositions of materials used for die attach adhesive. For example, a die attach adhesive can include a resin (liquid) and a filler (solid) which can settle out or become unevenly mixed within the resin. Thus a viscosity of the die attach adhesive dispensed from a syringe may not be constant through the entire quantity within the syringe, and viscosities across syringes can also vary across lots. Further, while ambient temperature is controlled within a production environments, temperature fluctuations can occur which would also affect the viscosity. A fluid generally has a lower viscosity at higher temperatures and a higher viscosity at lower temperatures.

Process testing to produce the reference values described above can include dispensing a first material at a first pressure, first duration, and first viscosity, producing a plan view image of the dispensed material, then measuring the volume of the dispensed adhesive. The first material is then dispensed at a second pressure at the first duration and first viscosity, then a plan view image of the dispensed material is produced and the volume is measured. By testing a variety of materials over a variety of pressures, durations, and viscosities, a data base (lookup table) can be produced to provide an adhesive volume for a given material dispensed at a given pressure and duration using a 2D plan view image of the material after it is dispensed onto a surface. For a given material dispensed at a uniform viscosity, the volume dispensed is linear with respect to dispense pressure.

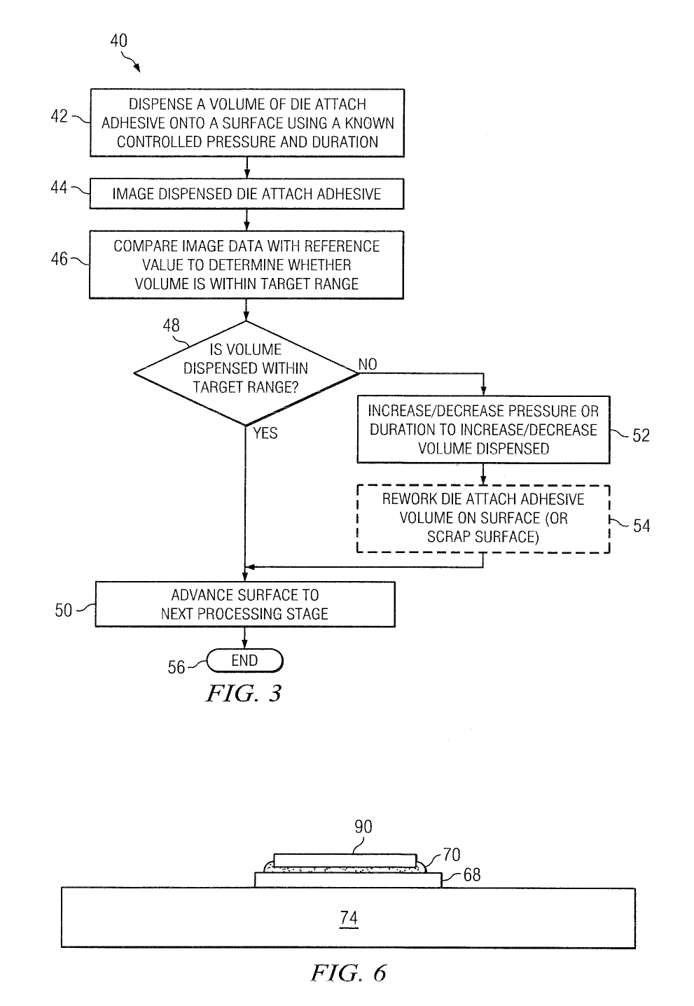

FIG. 3 is a flow chart of another embodiment of the present teachings. The FIG. 3 process 40 takes into account that a viscosity of a die attach adhesive can affect a flow of the adhesive across a surface onto which it is dispensed. A given volume of die attach adhesive at a first viscosity will flow across a surface less at a higher second viscosity and more at a lower third viscosity. Thus, unless viscosity is considered as described above, a plan view optical measurement (i.e. a 2D image) compared to a reference value may indicate that a correct volume of die attach adhesive is either deficient at a higher viscosity or excessive at a lower viscosity, which would result in a false positive error. Conversely, without considering viscosity, an incorrect volume of adhesive may be measured to be within a target range.

The FIG. 3 embodiment 40 begins at 42 with a volume (quantity) of die attach adhesive being dispensed onto a surface such as a lead frame die pad. The adhesive can be located within a container such as a syringe prior to dispensing. The adhesive can be dispensed using one or more of various techniques, such as by applying a known controlled pressure to a plunger to force the die attach adhesive from an aperture in the container, or by increasing the atmospheric pressure within the container using air pressure, etc., for a controlled period of time.

Once the adhesive is dispensed onto a surface 42, it is imaged 44, for example using an optical system (imaging system) which produces a plan view pixel image of the dispensed adhesive on the surface 30 such as that depicted in FIG. 2. The surface may be, for example, a lead frame die pad. A lead frame die pad area covered by the dispensed adhesive is measured.

For a given adhesive viscosity, the volume of material dispensed is proportional to the dispense pressure and duration. Thus the applied pressure and duration are known values and, as known parameters at process stage 42, they can be used along with the 2D image of the dispensed adhesive to determine the dispensed adhesive volume from a lookup table determined during process testing as described above. The image produced at 44 is compared with the reference value at 46 to determine the volume of material dispensed. If the volume dispensed is within a target range 48, the lead frame continues to the next processing stage 50, such as a die attach process. If the volume of die attach adhesive is not within a target range, the quantity of die attach adhesive dispensed onto successive lead frames can be changed, for example by altering the dispense pressure on the container or by changing the duration of time the adhesive is dispensed 52. Typically, the dispense duration will remain constant and the dispense pressure will be changed.

Because the quantity of die attach adhesive is determined prior to a die attach stage, the volume of die attach adhesive can be reworked 54 without handling a die. In an alternate embodiment, reworking the volume of die attach material on the surface is too costly, and thus a die is not attached to the surface and the surface is scrapped, thereby preventing the scrap of a potentially functional die. Where possible, however, the target range of the die attach volume at 48 can be smaller than a target range which would require rework or scrap, so that the volume at 52 can be adjusted before scrap or rework is necessary. Thus box 54 is shown as a dotted line, as rework or scrap is avoided where possible by adjusting the adhesive volume at 22 before scrap or rework is necessary.

The surface with the reworked die attach adhesive can then advance to the next processing stage 50, such as a die attach stage. After die attach, a post bond inspection can be performed, for example using an imaging system used to image the dispensed adhesive at the stage described in box 44, or another system.

In the FIG. 3 process, the volume of die attach adhesive can be automatically determined and adjusted without requiring operator input. The volume is preferably adjusted before rework or scrap is necessary. To change the dispensed volume, the dispense pressure placed on the die attach adhesive within the container can be automatically increased or decreased to dispense a larger or smaller volume of die attach adhesive. In another embodiment, rather than changing the pressure, the dispense duration is changed, with longer durations dispensing a larger quantity of adhesive.

Using this process, the quantity of adhesive dispensed can be adjusted in situ during production to automatically maintain a PBI variation range within a target range without productivity loss. Further, an automatic adjustment using a computer system will likely be more precise and faster than manual adjustments by an operator or technician, and therefore less costly. In addition, the attachment of a die to a volume of adhesive which is outside a target range is avoided. In a process including only a post bond inspection, an incorrect volume of adhesive is determined only after attachment of a die, which makes rework more difficult and scrap more costly.

Below is an equation which can be used to adjust the pressure on the die attach adhesive to change the volume dispensed:

$${Kpa}_{new} = Kpa * \{ 1 - Ratio * [ ( \frac{{\sum }_{i = 1}^{n} ( {Size}_{i} - {Size}_{learnt} ) * i}{{\sum }_{i = 1}^{n} i} ) / {Size}_{learnt} ] \}$$

In the equation:

“Kpa_{new}” is the adjusted dispensing pressure;

“Kpa” is the original dispensing pressure;

“Ratio” is a predefined pressure adjustment increment by which the pressure will be varied;

“Size,” is the measured 2D area of the dispensed die attach adhesive;

“Sizeₗₑₐᵣₙₜ” is the target (predicted) 2D reference area of the dispensed die attach adhesive for the current dispense pressure. Sizeₗₑₐᵣₙₜ is determined during prior process testing;

“i” is a weighting number which also represents the sample number. For example, the first volume dispensed is sample number 1 (“i”=1), the second volume dispensed is sample number 2 (“i”=2), etc. The weighting number considers that there is some time delay between dispensing the die attach adhesive and the inspection, and gives more weight to the later dispense volumes which will be closer in time to the inspection than the earlier dispense volumes; and

the summation in the equation denominator uses the weighting number “i” and is a weighting number.

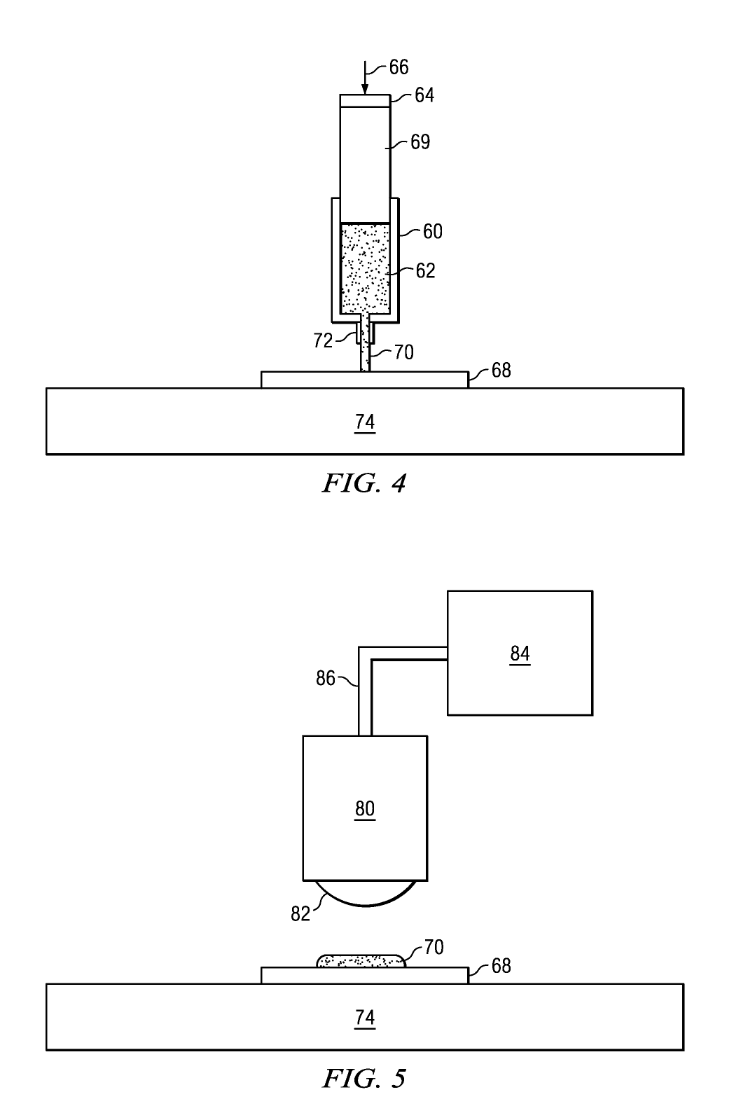

FIGS. 4 and 5 are schematic depictions of an apparatus which can be used during the manufacture of a semiconductor device to dispense a volume of die attach adhesive in accordance with an embodiment of the present teachings. The apparatus includes a dispenser adapted to dispense a volume of die attach adhesive onto a surface. In FIG. 4, a container 60 such as a syringe stores a volume of die attach adhesive 62. A pressure sensor 64 measures a dispense pressure 66 applied to the die attach adhesive 62 which is required to force a volume of die attach adhesive from the container 60 and onto a surface 68 such as a lead frame die pad. In this embodiment, the dispense pressure 66 measured by the sensor 64 is applied to the adhesive 62 within the container 60 using a plunger 68. Other techniques for forcing the adhesive 62 from the container 60, for example using the application of air pressure to effect the dispense pressure 66, are also contemplated. In this embodiment, a volume 70 of die attach adhesive 62 is forced from an aperture 72 in the syringe 60 and onto the lead frame die pad 68. During the dispensing of the die attach adhesive, the lead frame can rest on a workstation 74 of the assembly.

The pressure sensor 64 is a schematic depiction of a pressure sensor for exemplary purposes. The pressure sensor 64 can be attached to the plunger 68 of a syringe 60 as depicted, although other implementations are contemplated. For example, the pressure sensor can be part of a pressure pump which exerts pressure on the plunger or exerts pressure on the adhesive 62 within the container 60 through the use of air pressure. The pressure sensor can be part of a computer system which controls the dispensing and measuring of the die attach adhesive.

The duration of time the known pressure is applied to the die attach adhesive can be controlled by the computer system, for example a processor of the computer system. The duration of time can be set using an equation such as the one discussed above, or another equation. The computer system can default to a starting pressure and duration at startup, then adjust the pressure and/or duration as needed according to the equation discussed above, or according to a different rule set. The computer system can also store pressures and/or durations of previous production runs and initialize at a starting pressure and duration which represents an average of previous values.

FIG. 5 depicts an imaging system including an optical system 80 which can include a digital image sensor and a lens 82 which images the die attach adhesive 70 dispensed onto the surface 68. In use, the optical system 80 can provide a pixel image similar to that of FIG. 2 in data form, to a computer (computer system) 84 which can include a processor as a controller. The image data can be provided to the computer 84 from the optical system 80 via a data bus 86, for example using a cable, or wirelessly. The computer 84 uses the image data to measure a 2D surface area covered by the dispensed die attach adhesive.

The computer 84 also receives dispense pressure data from the pressure sensor 64 of FIG. 5. Dispense pressure data can be provided by the sensor 64 through a data bus such as a cable, or wirelessly. The dispense pressure applied to dispense the die attach adhesive and the surface area covered by the volume of the die attach adhesive on the surface are compared with a reference value to determine whether the volume of die attach adhesive is within a predefined (i.e. target) range.

The volume of dispensed adhesive 70 for a given dispense pressure 66 is inversely proportional to the viscosity of the die attach adhesive. The computer with the computer processor can be programmed using a set of instructions to compare the dispense pressure data and the image data to reference data obtained through testing as described above to determine the volume of dispensed die attach adhesive. The volume of dispensed die attach adhesive is compared with a target range to determine if an adjustment to the volume of dispensed die attach adhesive should be made.

If the dispensed volume is within a desired range of the target, the surface with the dispensed die attach adhesive is advanced to the next processing stage, for example die attach. FIG. 6 depicts a semiconductor die 90 attached to the surface 68 by the die attach adhesive 70 dispensed in accordance with an embodiment of the present teachings. The die attach adhesive 70 between an edge of the die 90 and the edge of the surface 68 is referred to as the die attach “fillet.” Dispensing a volume of die attach adhesive which is within a desired range of a target volume assists in forming a fillet having a correct width. An excessive volume of die attach adhesive 70 can result in die attach material covering an upper surface of the die 90, resulting in incorrect wire bonds or damage to the die. A deficient volume of die attach adhesive 70 can result in detachment of the die 90 from the surface 68.

If the dispensed volume is not within the desired range of the target, the volume of dispensed die attach adhesive on the surface can be adjusted by the computer processor. The computer can be further programmed using the set of instructions to adjust the dispensed volume of die attach adhesive by increasing or decreasing the pressure 66 on the plunger 68. In another embodiment, the dispense duration can be increased or decreased by the computer to dispense more or less adhesive at the given dispense pressure. In yet another embodiment, both the dispense pressure and dispense duration can be adjusted.

The target range for the dispensed volume of die attach adhesive is preferably small enough that scrap or rework is not necessary. That is, even though the dispensed volume may be outside the dispensed volume target range, the volume is still within a range which allows proper bonding of a die. Once it is determined that the dispensed volume is outside the dispensed volume target range, the dispensed volume can be adjusted before scrap or rework is necessary, and a die can be attached to the surface using the dispensed volume of adhesive.

Thus the present teachings can include a method and system which uses an optical image to measure a surface area of die attach adhesive dispensed onto a surface to determine the dispensed volume of die attach adhesive prior to attaching a die to the surface. The optical system can measure a two dimensional area of the dispensed die attach adhesive on the surface to determine whether the volume dispensed is sufficient. If the volume is insufficient or excessive, the dispensed die attach adhesive can be adjusted.

The present teachings can further include the application of a known die attach dispense pressure to dispense the die attach adhesive from a container onto the surface. The dispense pressure and a 2D image of the dispensed adhesive can be compared with a reference value to determine whether the volume of dispensed adhesive is sufficient. Because the reference values are determined using die attach adhesive viscosity and dispense pressure to determine the volume of adhesive from a 2D plan view image, a 2D image of the adhesive dispensed during production can be used, along with the dispense pressure, to determine the volume of dispensed adhesive during production.

The present teachings can further include a system which can provide automated adjustment of a volume of dispensed die attach adhesive through increased/decreased pressure to dispense the die attach adhesive, an increased/dispense duration, or both pressure and duration adjustments. The volume dispensed can be determined and changed using an automated system, and thus provides a die attach adhesive system having artificial intelligence (AI).

Various embodiments of the present teachings can be implemented through the use of a computer system, for example a computer system including a processor, executed through a set of instructions in the form of a computer program or software. The computer program or software may exist in a variety of forms, including in long-term storage, in execution by a computer system, and others. For example, the computer program can exist as software program(s) including program instructions in source code, object code, executable code or other formats; firmware program(s); or hardware description language (HDL) files. Any of the forgoing can be embodied on a computer readable medium, which can include storage devices, electronic memory, and signals, in compressed or uncompressed form. Exemplary computer readable storage devices or media include conventional computer system RAM (random access memory), ROM (read-only memory), EPROM (erasable programmable ROM), EEPROM (electrically erasable, programmable ROM), magnetic disks or optical disks, solid-state disks, or magnetic storage tapes. Computer programs or software can be distributed or accessed for instance via hard disk, solid state storage devices, CD-ROM, or via Internet download. In respects, the Internet itself, as an entity, can be regarded a computer readable medium, as can local area networks (LANs) and other computer networks in general.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, −2, −3, −10, −20, −30, etc.

While the present teachings have been illustrated with respect to one or more implementations, alterations and/or modifications can be made to the illustrated examples without departing from the spirit and scope of the appended claims. In addition, while a particular feature of the disclosure may have been described with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A method for forming a semiconductor device, comprising:
dispensing a die attach adhesive from within a container onto a surface by applying a die attach dispense pressure to the die attach adhesive within the container for a duration of time;
producing an image of the die attach adhesive dispensed onto the surface to produce image data;
comparing the image data and the die attach dispense pressure with one or more reference values to determine whether a volume of the dispensed die attach adhesive is within a target range; and
subsequent to producing the image of the die attach adhesive, attaching a semiconductor die to the surface.

2. The method of claim 1 wherein the die attach dispense pressure is a first die attach dispense pressure, the duration of time is a first duration of time, the surface is a first surface, the volume of dispensed die attach adhesive is a first volume of dispensed die attach adhesive, and the method further comprises:
determining that the first volume of the dispensed die attach adhesive is outside the target range;
dispensing a second volume of die attach adhesive which is different than the first volume of die attach adhesive onto a second surface which is different than the first surface using either a second die attach dispense pressure which is different than the first die attach dispense pressure or a second duration which is different than the first duration, or both.

3. The method of claim 1, further comprising:
determining that the volume of the dispensed die attach adhesive is outside the target range; and
attaching the semiconductor die to the surface using the volume of the dispensed die attach adhesive.

4. The method of claim 1 further comprising producing the image data with a method comprising:
producing a two dimensional image of the dispensed die attach adhesive on the surface with a digital image sensor; and
determining an area covered by the dispensed die attach adhesive on the surface from the two dimensional image.

5. The method of claim 4 further comprising:
subsequent to attaching the semiconductor die to the surface, performing a post bond inspection using the digital image sensor.

6. The method of claim 1 wherein the die attach dispense pressure is a first die attach dispense pressure, the surface is a first surface, and the method further comprises:
determining that the dispensed die attach adhesive is outside the target range;
responsive to determining that the dispensed die attach adhesive is outside the target range, changing the first die attach dispense pressure to a second die attach dispense pressure which is different than the first die attach dispense pressure; and
dispensing a die attach adhesive from within the container onto a second surface by applying the second die attach dispense pressure to the die attach adhesive within the container for a duration of time.

7. A method for forming a semiconductor device, comprising:
dispensing a first volume of die attach adhesive from within a container onto a first surface by applying a first die attach dispense pressure to the die attach adhesive within the container;
producing a first image of the first volume of die attach adhesive dispensed onto the first surface to produce first image data;
comparing the first image data and the first die attach dispense pressure with one or more reference values to determine whether the first volume of die attach adhesive is within a target range;
responsive to the first volume of die attach adhesive being outside the target range, dispensing a second volume of die attach adhesive different from the first volume of die attach adhesive from within the container onto a second surface by applying a second die attach dispense pressure different from the first die attach dispense pressure to the die attach adhesive within the container;
producing a second image of the second volume of die attach adhesive dispensed onto the second surface to produce second image data; and
comparing the second image data and the second die attach dispense pressure with one or more reference values to determine whether the second volume of die attach adhesive is within the target range.

8. The method of claim 7, further comprising:
attaching a first die to the first surface using the first volume of die attach adhesive; and
attaching the second die to the second surface using the second volume of die attach adhesive.

9. The method of claim 8, further comprising:
producing the first image of the first volume of die attach adhesive with a system comprising a digital image sensor;
producing the second image of the second volume of die attach adhesive with the system comprising the digital image sensor;
subsequent to attaching a first die to the first surface using the first volume of die attach adhesive, producing a third image of the first die attach adhesive with the system comprising the digital image sensor; and
subsequent to attaching the second die to the second surface using the second volume of die attach adhesive, producing a fourth image of the second die attach adhesive with the system comprising the digital image sensor.

10. An apparatus used to manufacture a semiconductor device, comprising:
a dispenser adapted to dispense a volume of die attach adhesive onto a surface;
an imaging system adapted to provide an image of the volume of dispensed die attach adhesive;
a computer adapted to determine a surface area covered by the volume of dispensed die attach adhesive on the surface using image data from the image produced by the imaging system; and
wherein the computer is further adapted to compare the surface area covered by the volume of the die attach adhesive on the surface with one or more reference values to determine whether the volume of die attach adhesive is within a target range.

11. The apparatus of claim 10, further comprising:
a pressure sensor adapted to measure a pressure applied to a die attach adhesive which is required to force a volume of die attach adhesive from a container and to dispense the volume of die attach adhesive onto a surface; and
wherein the computer is further adapted to compare the pressure applied to the die attach adhesive and the surface area covered by the volume of the die attach adhesive on the surface with one or more reference values to determine whether the volume of die attach adhesive is within a target range.

12. The apparatus of claim 10, further comprising:
the imaging system is adapted to image the dispensed die attach adhesive prior to attaching a semiconductor die to the dispensed adhesive.

13. The apparatus of claim 12, further comprising:
the imaging system is further adapted to image the dispensed die attach adhesive subsequent to attaching a semiconductor die to the dispensed adhesive.

14. A method for forming a semiconductor device implemented using a computer system, comprising:
dispensing a die attach adhesive from within a container onto a surface by applying a die attach dispense pressure to the die attach adhesive within the container for a duration of time;
producing an image of the die attach adhesive dispensed onto the surface using an imaging system to produce image data;
using a computer system processor, comparing the image data and the die attach dispense pressure with one or more reference values to determine whether a volume of the dispensed die attach adhesive is within a target range; and
subsequent to producing the image of the die attach adhesive, attaching a semiconductor die to the surface using a die attach apparatus.

15. The method of claim 14, further comprising:
the dispensing of the die attach adhesive from within the container onto the surface by applying the die attach dispense pressure to the die attach adhesive within the container for the duration of time is performed using a set of instructions implemented using a computer processor;
controlling the imaging system using the computer system; and
controlling the die attach system using the computer system.

16. A computer-readable medium storing a set of instructions which causes a computer system to perform a set of instructions to execute a method comprising:
dispensing a die attach adhesive from within a container onto a surface by applying a die attach dispense pressure to the die attach adhesive within the container for a duration of time;
producing an image of the die attach adhesive dispensed onto the surface to produce image data;
comparing the image data and the die attach dispense pressure with one or more reference values to determine whether a volume of the dispensed die attach adhesive is within a target range; and
subsequent to producing the image of the die attach adhesive, attaching a semiconductor die to the surface.
